(19) United States
(12) Patent Application Publication
(10) Pub. No.: US 2003/0075753 A1
(43) Pub. Date: Apr. 24, 2003

(54) Stacked capacitor and method for fabricating the same

(76) Inventors: Chung-Ming Chu, Tainan Hsien (TW); Masuhiro Kiyotoshi, Yokohama (JP); Masatoshi Fukuda, Yokohama (JP); Tosiya Suzuki, Yokohama (JP); Min-Chieh Yang, Kaohsiung (TW)

Correspondence Address: FISH & RICHARDSON PC, 225 FRANKLIN ST, BOSTON, MA, 02110, US

(21) Appl. No.: 10/243,554

(22) Filed: Sep. 13, 2002

(30) Foreign Application Priority Data
Sep. 14, 2001 (TW) 090122837

(51) Int. Cl. H01L 21/8242; H01L 27/108; H01L 29/76; H01L 29/94; H01L 31/119; H01L 21/20

(52) U.S. Cl. 257/308; 438/240; 438/397; 438/254; 257/309; 257/310

(57) ABSTRACT

A stacked capacitor on a contact plug of a semiconductor substrate and the method for fabricating the same. A cylindrical conductive layer is formed upon a contact plug of a semiconductor substrate as a lower electrode of a stacked capacitor and there is an opening in the cylindrical conductive layer. A barrier layer is deposited inside the opening of the cylindrical conductive layer and fills a portion of the opening. A capacitor dielectric layer is deposited on the cylindrical conductive layer and on the barrier layer and an upper electrode layer is formed on the capacitor dielectric layer to complete the stacked capacitor.

### FIELD OF THE INVENTION

The present invention relates to semiconductor fabrication, and more particularly to a stacked capacitor and the method for fabricating the same.

### BACKGROUND OF THE INVENTION

Ferro-electric materials, such as zirconate titanate (PZT), strontium bismuth tantalate (SBT), BaSrTiO₃ (BST) or SrTiO₃(ST), are used as dielectric layers of a capacitor, which is deposited or annealed at high temperature in oxygen to obtain crystallized dielectric films. Contact plugs are easily oxidized under oxygen-rich high temperature conditions, and the contact resistance is raised due to plug oxidation.

As disclosed in the report of C. S. Hwang (Samsung Electronics) in Materials Science and Engineering B56, 178-190, 1998, the difficulties raised during process integration of ferro-electric capacitors are mostly due to the fact that the storage node materials, e.g. Pr, Ru, Ir and conductive metal oxides, require a barrier metal layer (BM) at the interface with the poly-Silicon or W plug, which connects the capacitor with the cell transistor. FIG. 1 shows a conventional ferro-electric capacitor structure. The ferro-electric capacitor is constructed upon a bit line 10, comprising a storage electrode 12, a ferro-electric capacitor dielectric layer 14 and a relative electrode 16. Binary or ternary refractory metal nitrides (such as TiN TiSiN or TiAlN) are used as a barrier layer 19 on the contact plug 18 to protect the contact plug 18 from reacting with the above storage electrode 12 during high temperature annealing, deposition of ferro-electric material or insulating layer. However, it is difficult for the barrier layer 19 to maintain good electrical conductivity after these processes. K. Hieda (Toshiba semiconductor corporation) reported in IEDM (1999) that TiAlN is used as a barrier layer between SrRuO₃ storage node and W plug to prevent the reaction between of SrRuO₃ and W. The problem is that the thermal stability of TiAlN barrier layer is not satisfied. The barrier layer of TiAlN is easily oxidized under oxygen-rich high temperature processes, e.g. ferro-electric material deposition or annealing in oxygen, and oxygen will probably penetrate through the barrier layer and then oxidize the contact plug, which results in the raising of contact resistance.

It is not sufficient to prevent oxygen diffusion merely by forming a barrier layer between the storage electrode and the contact plug. There is a need to improve the structure of stacked capacitor to achieve better electrical properties.

As the density of the transistors increases, the design rule of semiconductor devices becomes more integrated. The design rule will be toward 0.11 or 0.1 μm in next generation DRAM. In such cases, the height of storage node is over 500 nm and the aspect ratio is greater than 5 during ferro-electric layer deposition. After preliminary experiments with respect to the high aspect ratio of ferro-electric film conformity, the results according to this invention show that the step coverage of SrTiO₃ film is very poor (40% approximately, very thin SrTiO₃ film in the bottom). Furthermore, the composition controllability at the bottom of the inside cylinder is not satisfied as a storage node because of leakage. According to the above results, the inside bottom of the cylinder is not suitable as a storage node.

### SUMMARY OF THE INVENTION

One object of the present invention is to provide a cylindrically-structured capacitor and a method for fabricating the same to prevent the oxygen diffusion that results in the oxidation of barrier layer or contact plug.

Another object of the present invention is to provide a cylindrically-structured capacitor and a method for fabricating the same to improve step coverage of ferro-electric layer in a high aspect cylindrical electrode.

To achieve the above objects, a robust material that bars oxygen diffusion, such as SiN, Ta₂O₅ or Al₂O₃, is formed on the cylinder storage electrode as a second barrier layer and covers the bottom of the cylinder. The second barrier layer prevents oxygen penetrating through the first barrier layer and the contact plug beneath during capacitor dielectric layer deposition, and the wet etching solution penetration is also avoided during storage electrode formation. Moreover, the aspect ratio is reduced because of deposition of the second barrier layer in the bottom of the cylinder, and therefore, the capacitor leakage is also reduced because of no leakage area in the interface.

A stacked capacitor is provided according to the present invention, comprising: a cylindrical conductive layer as a lower electrode of the stacked capacitor, wherein an opening is in the cylindrical conductive layer; a barrier layer inside the opening of the cylindrical conductive layer and filling a portion of the opening; a capacitor dielectric layer on the cylindrical conductive layer and on the barrier layer; and an upper electrode layer on the capacitor dielectric layer.

Another stacked capacitor is provided according to the present invention, comprising: a cylindrical conductive layer as a lower electrode of the stacked capacitor, wherein an opening is in the cylindrical conductive layer; a barrier layer lining the lower portion and bottom of the opening of the cylindrical conductive layer; a capacitor dielectric layer on the cylindrical conductive layer and on the barrier layer; and an upper electrode layer on the capacitor dielectric layer.

A method of fabricating a stacked capacitor is provided according to the present invention, comprising the steps of: providing a semiconductor substrate comprising a first insulating layer and a contact plug embedded in the first insulating layer; forming a second insulating layer and a third insulating layer on the semiconductor substrate in sequence; removing a portion of the second insulating layer and the third insulating layer to form an opening and exposing the contact plug; depositing a first barrier layer and a first conductive layer in sequence on the opening and the third insulating layer and depositing a second barrier layer on the first conductive layer, wherein the second barrier layer fills the opening or not by controlling deposition thickness; recessing the second barrier layer until the surface of the second barrier layer is below the top of the opening; removing the first conductive layer beyond the opening and forming a cylindrical conductive layer in the opening as a lower electrode of the stacked capacitor; recessing the third insulating layer and the first barrier layer until the second insulating layer is exposed; forming a capacitor dielectric layer on the second barrier and the cylindrical conductive layer; and forming an upper electrode layer on the capacitor dielectric layer.

### BRIEF DESCRIPTION OF THE DRAWINGS

The present invention will become more fully understood from the detailed description given herein below and the accompanying drawings, given by way of illustration only and thus not intended to be limitative of the present invention. In the drawings,

FIG. 1 is a schematic view of the conventional structure showing a binary or ternary refractory metal nitride formed as a barrier layer between a storage electrode and a contact plug;

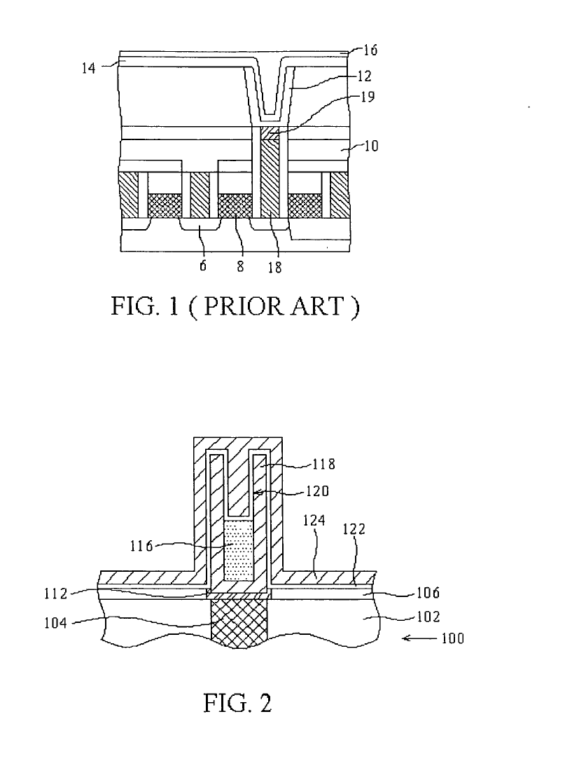

FIG. 2 is a schematic view of a capacitor structure in the first embodiment according to the present invention.

FIGS. 3A through 3F are schematic cross-sections illustrating the fabrication flow of the capacitor in FIG. 2;

FIG. 4 is a schematic view of a capacitor structure in the second embodiment according to the present invention;

FIG. 5 is a schematic view of a capacitor structure in the third embodiment according to the present invention; and

FIG. 6 is a schematic view of a capacitor structure in the fourth embodiment according to the present invention.

### DETAILED DESCRIPTION OF THE INVENTION

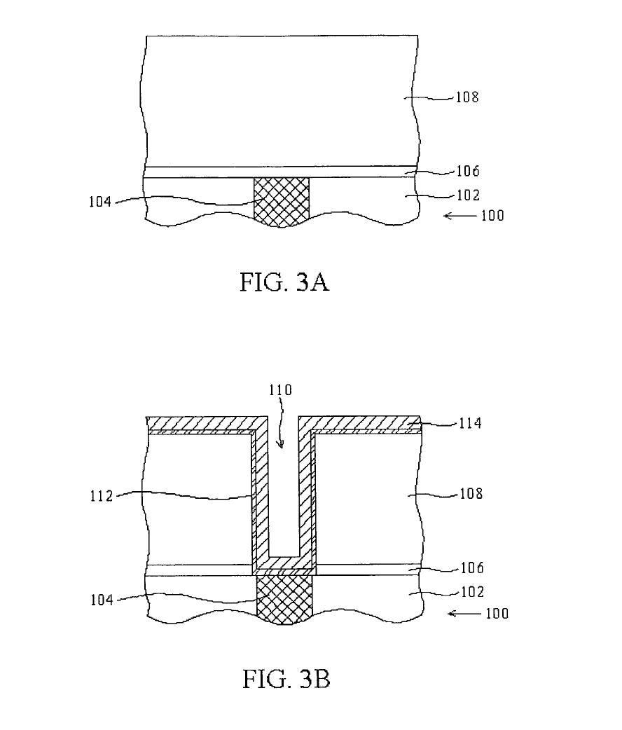

FIG. 2 is a schematic view of a capacitor structure in the first embodiment according to the present invention. A capacitor according the present invention is formed upon a contact plug 104 above a semiconductor substrate 100. A cylindrical conductive layer 118 acts as a lower electrode of the capacitor, wherein there is an opening 120 inside the cylindrical conductive layer 118. A barrier layer 116 is formed inside the cylindrical conductive layer 112 and fills a portion of the opening 120. A capacitor dielectric layer 122 is formed on the barrier layer 116 and the lower electrode 118. An upper electrode layer 124 is formed on the capacitor dielectric layer 122 and the cylindrical capacitor is completed.

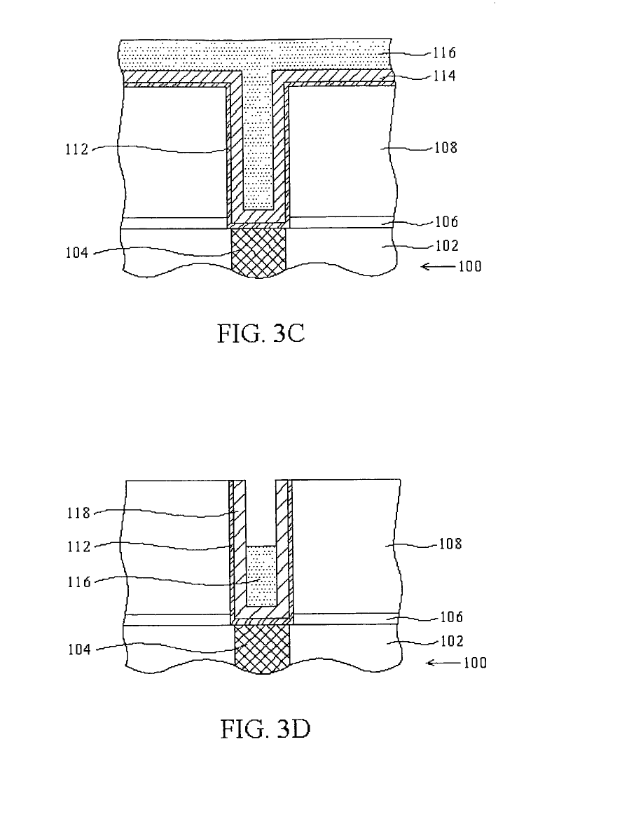

FIGS. 3A through 3F are schematic cross-sections illustrating the fabrication flow of the capacitor in FIG. 2. Like elements in FIG. 2 and FIGS. 3A through 3G are denoted with the same numbers.

In the following description, “substrate” represents a semiconductor wafer with predetermined device and/or film thereon, and “surface of the substrate” represents the exposed surface of the wafer, such as a surface layer, insulating layer or metal layout on the wafer. In FIG. 3A, a first insulating layer 102 is formed on a semiconductor substrate 100 and a contact plug 104 is embedded in the first insulating layer. There can be MOS devices, bit lines, logic devices or poly-silicon plugs on the semiconductor substrate 100 if needed, though they are not shown in the figures.

The contact plug 104 is formed by depositing a first insulating layer 102 on the surface of the substrate, such as silicon oxide in the thickness of 200˜1000 nm, and then a plurality of contact holes with diameter 0.07˜0.2 μm are defined by lithography and etching on the first insulating layer 102. A poly-silicon layer is deposited in the contact holes and recessed by Chemical Dry Etching (CDE) or Reactive Ion Etching (RIE) until the surface of the polysilicon layer below the first insulating layer above 100˜500 nm in depth to form poly-silicon plugs. Composite W plugs are formed by depositing W plugs upon the polysilicon plugs and planarizing the surface of W plugs to be even with the first insulating layer by chemical mechanical polishing (CMP) or RIE.

A second insulating layer 106 and a third insulating layer 108 are formed on the first insulating layer 102 and the contact plug 104 in sequence. The second insulating layer 106 is used as an etching-stopped layer and the material can be silicon nitride or oxynitride with a thickness of 10˜100 nm. The material of the third insulating layer can be silicon oxide in the thickness of 300˜1000 nm.

In FIG. 3B, a pre-defined area of the third insulating layer 108 and the second insulating layer 106 are removed by lithography and etching until the surface of the contact plug 104 is exposed and then an opening 110 is formed with a diameter about 0.1˜0.2 μm and the tilting angle inside the opening 110 is about 80·90°. A conformal first barrier layer 112 is deposited on the first insulating layer 108 and the opening 110 and the material can be TiN TiSiN or TiAlN. A conductive layer 114 is deposited on the first barrier layer as a lower electrode layer and the material can be noble metals, such as Pt, Ir or Ru, or conductive metallic oxides, such as IrO₂ or RuO₂. The key point is that the conductive layer does not fill up the opening 110.

FIG. 3C shows a key step according to the present invention. A second barrier layer 116 is deposited on the lower electrode 114 and fills the opening 110. The reason for use of a robust material, such as SiN Ta₂O₅ or Al₂O₃, for the second barrier layer is to bar oxygen diffusion and Ta₂O₅ is preferred. The second barrier layer 116 is recessed to a thickness of 100˜500 nm by chemical dry etching or reactive ion etching to the surface of the second barrier layer below the opening 110 as shown in FIG. 3D. The conductive layer 114 above the third insulating layer 108 is removed by chemical mechanical polishing or reactive ion etching and only the conductive layer 114 in the opening 110 is left. The conductive layer remaining in the opening 110 is a hollow cylindrical conductive layer 118 as a lower electrode of the capacitor.

The third insulating layer 108 and the first barrier layer 112 are recessed by wet or dry etching until the second insulating layer is exposed and the outer surface of the cylindrical lower electrode is exposed as shown in FIG. 3E. In FIG. 3E, there is a shallow opening 120 left (100˜500 nm) due to the second barrier layer 116 being pre-deposited in the cylindrical lower electrode 118, which improves the following deposition of capacitor dielectric layer.

In FIG. 3F, a conformal capacitor dielectric layer 122 and an upper electrode layer 124 are deposited in sequence on the surface of the second insulating layer 106, the second barrier layer 116 and the lower electrode 118 to complete a capacitor. The thickness of the capacitor dielectric layer is about 10˜40 nm and the material can be lead zirconate titanate (PZT) strontium bismuth tantalite (SBT) BaSrTiO₃ (BST) or SrTiO₃ (ST). The thickness of the upper electrode 124 can be about 20˜100 nm and the material can be noble metals, such as Pt, Ir or Ru.

Compared to the conventional structure in which only one barrier layer is formed below the storage electrode, a second barrier layer 116 is proposed according to the present invention by forming a robust material, e.g. SiN Ta₂O₅ or Al₂O₃, on the cylindrical storage electrode covering the bottom of the cylinder to prevent oxygen diffusion. The second barrier layer 116 prevents oxygen penetrating through the below barrier layer or plugs during the capacitor dielectric layer 122 deposition. The second barrier layer 116 also prevents the penetration of the wet etching solution during the storage electrode 118 formation. Furthermore, the aspect ratio is reduced because of pre-deposition of the second barrier layer 116 in the bottom of the opening 120, and therefore, the capacitor leakage is also reduced because of no leakage area in the interface.

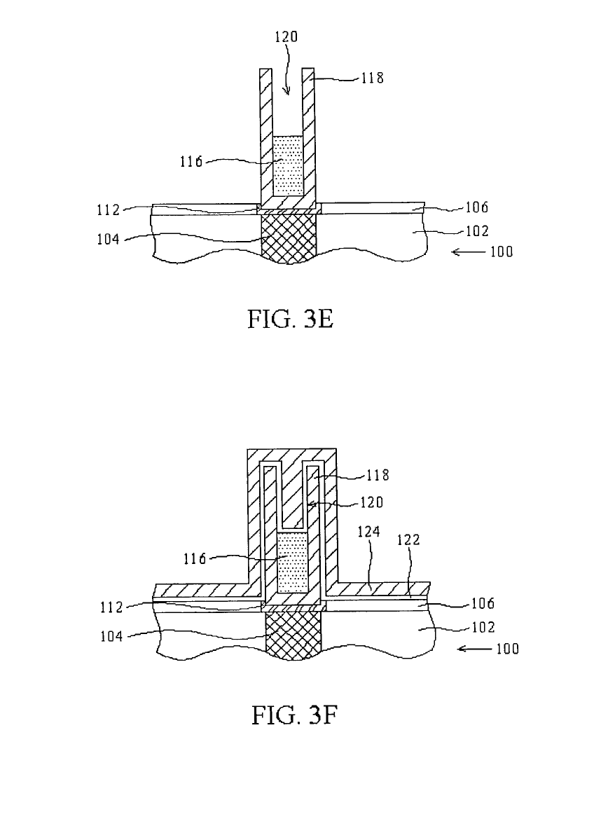

FIG. 4 is a schematic view of a capacitor structure in the second embodiment according to the present invention. Like elements in FIG. 2 and FIG. 4 are denoted by like numbers and analogical elements are denoted as the same number with an “a”. In FIG. 4, a thinner second barrier layer 116a is lined inside the bottom and the lower surface of the cylindrical lower electrode 120. This can be achieved by not filling up the cylinder with the barrier material and then recessing the barrier layer to form a second barrier layer 116a as shown in FIG. 4.

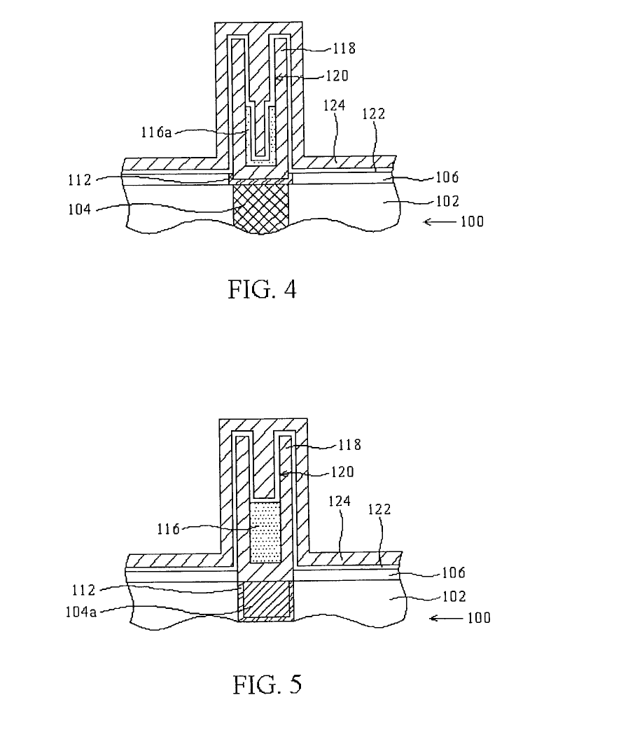

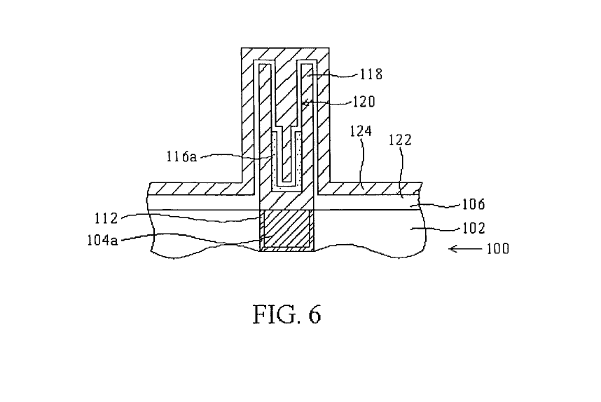

In the third and fourth embodiments according to the present invention, the material of contact plug 104 is identical with the lower electrode, such as noble metal plug: Ru plug as shown in FIGS. 5 and 6. The oxygen diffusion into the lower electrode and the contact plug can be further avoided to ensure sufficient thickness of the metallic lower electrode 118.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A stacked capacitor on a contact plug of a semiconductor substrate, comprising:
a cylindrical conductive layer as a lower electrode of the stacked capacitor, wherein an opening is in the cylindrical conductive layer;
a barrier layer inside the opening of the cylindrical conductive layer and filling a portion of the opening;
a capacitor dielectric layer on the cylindrical conductive layer and the barrier layer; and
an upper electrode layer on the capacitor dielectric layer.

2. The stacked capacitor as claimed in claim 1, wherein the material of the cylindrical conductive layer is Pt, Ru, Ir, IrO₂, or RuO₂.

3. The stacked capacitor as claimed in claim 1, wherein the material of the cylindrical conductive layer is Ru.

4. The stacked capacitor as claimed in claim 1, wherein the material of the barrier layer is SiN, Ta₂O₅ or Al₂O₃.

5. The stacked capacitor as claimed in claim 1, wherein the material of the barrier layer is Ta₂O₅.

6. The stacked capacitor as claimed in claim 1, wherein the material of the capacitor dielectric layer is zirconate titanate (PZT), strontium bismuth tantalate (SBT), BaSrTiO₃ (BST) or SrTiO₃ (ST).

7. The stacked capacitor as claimed in claim 1, wherein the material of the upper electrode layer is Pt, Ir or Ru.

8. The stacked capacitor as claimed in claim 1, wherein the contact plug comprises W.

9. The stacked capacitor as claimed in claim 8, wherein another barrier layer is between the contact plug and cylindrical conductive layer.

10. The stacked capacitor as claimed in claim 1, wherein the contact plug comprises Ru.

11. A stacked capacitor on a contact plug of a semiconductor substrate, comprising:
a cylindrical conductive layer as a lower electrode of the stacked capacitor, wherein an opening is in the cylindrical conductive layer;
a barrier layer lining the lower portion and bottom of the opening of the cylindrical conductive layer;
a capacitor dielectric layer on the cylindrical conductive layer and the barrier layer; and
an upper electrode layer on the capacitor dielectric layer.

12. The stacked capacitor as claimed in claim 11, wherein the material of the cylindrical conductive layer is Pt, Ru, Ir, IrO₂, or RuO₂.

13. The stacked capacitor as claimed in claim 11, wherein the material of the cylindrical conductive layer is Ru.

14. The stacked capacitor as claimed in claim 11, wherein the material of the barrier layer is SiN, Ta₂O₅ or Al₂O₃.

15. The stacked capacitor as claimed in claim 11, wherein the material of the barrier layer is Ta₂O₅.

16. The stacked capacitor as claimed in claim 11, wherein the material of the capacitor dielectric layer is zirconate titanate (PZT), strontium bismuth tantalate (SBT), BaSrTiO₃ (BST) or SrTiO₃ (ST).

17. The stacked capacitor as claimed in claim 11, wherein the material of the upper electrode layer is Pt, Ir or Ru.

18. The stacked capacitor as claimed in claim 11, wherein the contact plug comprises W.

19. The stacked capacitor as claimed in claim 18, wherein another barrier layer is formed between the contact plug and the cylindrical conductive layer.

20. The stacked capacitor as claimed in claim 11, wherein the contact plug comprises Ru.

21. A method of fabricating a stacked capacitor, comprising the steps of:
(a) providing a semiconductor substrate comprising a first insulating layer thereon and a contact plug embedded in the first insulating layer;
(b) forming a second insulating layer an a third insulating layer on the semiconductor substrate in sequence;
(c) removing a portion of the second insulating layer and the third insulating layer to form an opening and exposing the contact plug by lithography and etching;
(d) depositing a first barrier layer and a first conductive layer in sequence on the opening and the third insulating layer;
(e) depositing a second barrier layer on the first conductive layer and recessing the second barrier layer untill the surface of the second barrier layer is below the top of the opening;
(f) removing the first conductive layer beyond the opening and forming a cylindrical conductive layer in the opening as a lower electrode of the stacked capacitor;
(g) recessing the third insulating layer and the first barrier layer untill the second insulating layer is exposed;
(h) forming a capacitor dielectric layer on the second barrier and the cylindrical conductive layer; and
(i) forming an upper electrode layer on the capacitor dielectric layer.

22. The method as claimed in claim 21, wherein the materials of the first insulating layer and the third insulating layer are silicon oxide.

23. The method as claimed in claim 21, wherein the material of the second insulating layer is silicon nitride.

24. The method as claimed as claim 21, wherein the contact plug comprises W.

25. The method as claimed in claim 21, wherein the contact plug comprises Ru.

26. The method as claimed in claim 21, wherein the material of the first barrier is TiN, TiSiN, or TiAlN.

27. The method as claimed in claim 21, wherein the material of the second barrier is SiN, Ta₂O₅ or Al₂O₃.

28. The method as claimed in claim 21, wherein the material of the second barrier is Ta₂O₅.

29. The method as claimed in claim 21, wherein the material of the first conductive layer is Pt, Ru, Ir, IrO₂, or RuO₂.

30. The method as claimed as in claim 21, wherein the material of the capacitor dielectric layer is zirconate titanate (PZT), strontium bismuth tantalate (SBT), BaSrTiO₃ (BST) or SrTiO₃ (ST).

31. The method as claimed in claim 21, wherein the material of the upper electrode is Pt, Ir and Ru.

32. The method as claimed in claim 21, wherein in the step (e) depositing the second barrier layer on the first conductive layer fills up the opening with the second barrier layer.

33. The method as claimed in claim 21, wherein in the step (e) depositing the second barrier layer on the first conductive layer does not fill up the opening with the second barrier layer.
